(19) United States
(12) Patent Application Publication
(10) Pub. No.: US 2012/0033352 A1
(43) Pub. Date: Feb. 9, 2012

(54) Motor Control Center Subunit(s) (bucket(s)) with compartmentalized disconnect associated with a distinctly separate load section.

(76) Inventor: Bruce William Grindeland, Franklin, WI (US)

(21) Appl. No.: 13/198,193

(22) Filed: Aug. 4, 2011

Related U.S. Application Data
(60) Provisional application No. 61/370,896, filed on Aug. 5, 2010.

(51) Int. Cl. H05K 7/00

(52) U.S. Cl. 361/622

(57) ABSTRACT

A Motor Control Center Subunit(s) (bucket(s)) with compartmentalized disconnect associated with a distinctly separate load compartment, consisting of multiple compartments arranged so as to allow service of the load compartment without exposure to line voltages. The invention removes the energized components from the associated loads they are feeding, thereby greatly reducing the health risks and decreasing the cumbersome nature of legally necessary methods and procedures that a person working within such a compartment would currently have to ascribe to. A key feature/distinction of this invention is that the disconnecting devices is remote mounted from the load controlling components, so that when the handle operator is switched to the OFF position there are no components (e.g. disconnecting device and/or its conductors) within the load compartment that remain energized by line voltage.

### CROSS-REFERENCE TO RELATED APPLICATIONS

This system/assembly I have described can be used in the way I described a previous provisional patent(s) which I, Bruce William Grindeland, have filed (Application No: 61/370,896, Filing or 371(c) Date Aug. 5, 2010). This system/assembly also utilizes some concepts similar to those of (a) non-provisional patent(s) application(s) I have filed (Application No: 61/367,923 EFS ID: U.S. Pat. No. 8,095,378, application Ser. No: 13/190,337 EFS ID: U.S. Pat. No. 10,593,378, application Ser. No: 13/190,409 EFS ID: U.S. Pat. No. 10,593,981).

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM LISTING COMPACT DISC APPENDIX

Not Applicable

### BACKGROUND OF THE INVENTION

The present invention relates to a Motor Control Center Subunit(s) (bucket(s)) with compartmentalized disconnect associated with a distinctly separate load section.

Herein, where compartment is used as a descriptor, it is meant to describe the compartmentalization of the disconnect housing and the load housing. This is referred to as being achieved through either; separate compartments within the same subunit, or distinctly separate subunits. The key factor is that the interlocked handle provides access to load compartment, not disconnecting device.

Commonly, in motor control centers, disconnecting means associated with loads housed by the motor control center are contained within the same Subunit/compartment that is fed by a disconnecting means (i.e. the line side of the disconnect is still energized and as such the disconnect is still an energized component). This causes risks of arc flash and otherwise dangerous conditions to a person that is exposed to a Subunit/compartment that follows this conventional means of assembly. Proper safety methods and procedures are cumbersome, leading to the potential for a person to not engage in the methods and/or procedures that are legally required to work within such a compartment and exposing themselves to unnecessary risks.

It would therefore be desirable to design a Motor Control Center Subunit(s) (bucket(s)) with compartmentalized disconnect associated with a distinctly separate load section to make compliance with laws and regulations less cumbersome.

### BRIEF SUMMARY OF THE INVENTION

My invention isolates, through compartmentalization, energized components apart from de-energized components, decreasing the hazards and cumbersome nature as it applies to the components included. My invention includes an operator that grants access to the compartment which can be completely de-energized and does NOT grant access to the compartment which still houses energized parts (to gain access to this compartment you would have to use special tools). My invention would also achieve a reduction in how often the disconnecting means, itself, would be disconnected from the MCC Bus by allowing the load compartment to be removed independently of the disconnect (when built as two separate subunits).

### BRIEF DESCRIPTION OF THE DRAWING

The Drawings demonstrate one solution for a preferred embodiment of the described invention. These drawings are intended to depict my invention as it would be integrated with typical low-voltage motor control centers.

Displayed in the drawings:

FIG. 1A is a drawing that depicts a subplate view of one method of the preferred embodiment of my invention and displays a typical arrangement of the components, and the interconnection of those components.

FIG. 1B is a drawing that depicts a front elevation view of one method of the preferred embodiment of my invention and displays a typical arrangement of the components, and doors or plates that would be visible from standing in front of the assembly.

### DETAILED DESCRIPTION OF THE INVENTION

The following description makes reference to line voltage. It is appreciated that such a term may refer to a variety of both common voltage ranges and unique voltages depending on context. However, it is appreciated that the present invention is intended for use in typical low-voltage (<600V) electrical systems and the purpose of the invention is to simplify compliance with safety regulations and procedures during maintenance. A typical example would consist of a system wherein supply voltage is 480 volts 3-phase. My invention describes an improvement to commonly used low-voltage motor control centers. Motor control centers are in common use in the electrical field and often referred to as MCC's.

Referring to the Drawings, a typical arrangement of the components in a preferred embodiment of the invention is shown. The overall enclosure, or MCC unit, contains within it a disconnecting device and load device(s) as commonly used in applications of electrical systems but isolated into separate compartments. Components include the disconnecting device, mechanical linkage or flexible cable, an operating handle, low-voltage motor control center, auxiliary optional components, lugs, thru-wall terminals, wireways/gutters, hinges, securing devices, and load device(s).

The general appearance of the invention is similar to that of a common low-voltage motor control centers. However, there are important and distinct differences between the present invention and existing low-voltage motor control center designs.

In motor control centers, disconnecting means associated with loads housed by the motor control center are contained within the same subunit/compartment. Because of this, when a load associated with a disconnect that is in the OPEN or OFF state, there continue to be live components contained within the subunit/compartment that is fed by a disconnecting means (e.g. the line side of the disconnect is still energized and as such the disconnect is still an energized component). This causes risks of arc flash and otherwise dangerous conditions to a person that is exposed to a subunit/compartment that follows this conventional means of assembly. Proper safety methods and procedures are cumbersome, leading to the potential for a person to not engage in the methods and/or procedures that are legally required to work within such a compartment and exposing themselves to unnecessary risks.

The present invention is distinctly different from existing; I will expound upon the differences and improvements.

The first distinction is that in the preferred embodiment of my invention requires an additional compartment, whether within the same subunit or as separate subunits, be added to contain a disconnecting device which feeds a load compartment that is also housed by the same motor control center section or subunit so that ALL components in the load compartment are de-energized by the remote disconnecting device via operator/linkage. The operator on the load compartment opens/closes the disconnecting device in the disconnect compartment and is interlocked with the load compartment door but NOT the disconnect compartment door. This disconnect compartment requires special tools (e.g. screwdriver) to gain access to it.

Secondly, in the preferred embodiment; my invention isolates, through compartmentalization, energized components apart from de-energized components, decreasing the hazards and cumbersome nature as it applies to the components included. My invention includes an operator that grants access to the compartment which can be completely de-energized and does NOT grant access to the compartment which still houses energized parts (To gain access to this compartment you would have to use special tools). The conventional method still has the energized components being granted access to by the door operator; they are housed in the same compartment. It is also achieving a reduction in how often the disconnecting means, itself, be disconnected from the motor control center bus by allowing the load compartment to be removed independently of the disconnect (when built as two separate subunits).

It is a purpose of my invention to simplify compliance with safety regulations, thereby encouraging compliance.

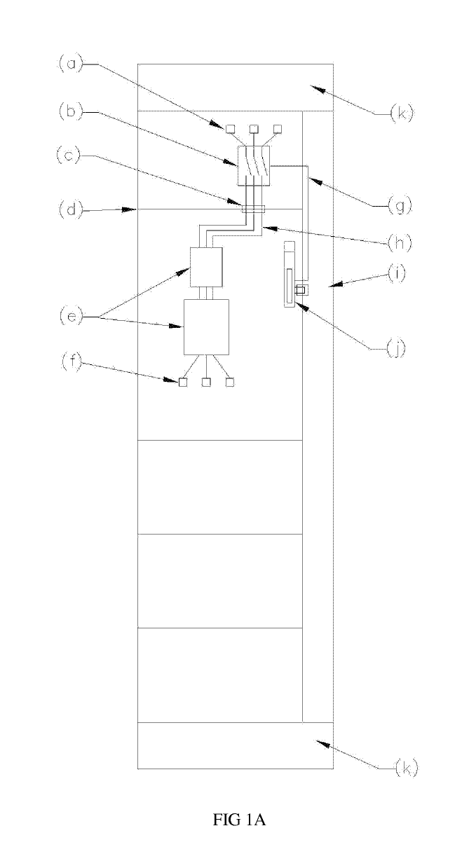

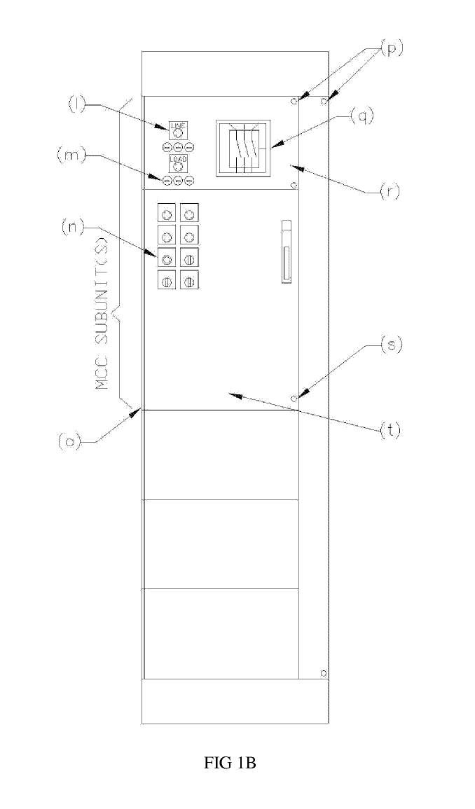

Referring again to FIG. 1A, (a) is a representation of thru-barrier connection(s) (stabs) to the bus. The bus referred to here is that of a typical low-voltage motor control center. This is where the electric power would be fed into the system I am describing.

Referring again to FIG. 1A, (b) is a representation of the disconnect component within the system.

Referring again to FIG. 1A, (c) is a representation of; a plug/receptacle, thru-wall terminals, hard-wired interconnection, or the like. This component is one method in the preferred embodiment of my invention to send power from the disconnect compartment to the load compartment.

Referring again to FIG. 1A, (d) indicates a barrier between the disconnect and load compartment(s). This barrier is essential to the functionality of my invention, as I have described within this document.

Referring again to FIG. 1A, (e) is indicating a plurality of miscellaneous load components. In the preferred embodiment of my invention there could be 1 or a plurality of load components. The load component(s) could be any of several typical load controlling devices that are in common use (e.g. Full Voltage Starters, Reduced Voltage Soft Starters, Variable Frequency Drives, Fuses, etc.)

Referring again to FIG. 1A, (f) is depicting load lugs which would act as a location for connecting motor leads into the circuit/system which I am describing in one method of a preferred embodiment of my invention. The load lugs are non-essential to my invention and may or may not be utilized.

Referring again to FIG. 1A, (g) is depicting the disconnect/operator linkage which would interlock the disconnecting device with the load compartment door. This linkage, which could be achieved in a multitude of manners, is an essential part of one method of the preferred embodiment of my invention.

Referring again to FIG. 1A, (h) is depicting conductors which electrically connect the individual components within the overall system that I am describing. Displayed in this one method of a preferred embodiment of my invention is what is typically referred to as 3-phase power, as is commonly used in systems within this inventions field of application.

Referring again to FIG. 1A, (i) is referring to a wireway or wire gutter as is commonly utilized in low-voltage motor control centers.

Referring again to FIG. 1A, (j) is depicting a door operator for the load compartment which is interlocked with the state of the disconnecting device which is located within the disconnect compartment. In a preferred method of my invention this device would grant access to the load compartment when the disconnect device is in an OFF or OPEN state and hinder access to the load compartment when the disconnect device is in an ON or CLOSED state.

Referring again to FIG. 1A, (k) in both cases is referring to a wire gutter space as is commonly used in low-voltage motor control centers. One of the “(k)'s” is referring to the top gutter space and the other to the lower gutter space, respectively.

Referring to FIG. 1B, (l) is referring to an indicating light with a nameplate that would be illuminated when voltage was present on the line side of the disconnecting device. This same technique could be used on the load side of the disconnecting device, as is depicted. Neither of these occurrences are necessary for my invention to perform as functionally intended but could act as a method of improving my invention for the purpose of a higher level of convenience.

Referring again to FIG. 1B, (m) is referring to a set of voltage present test points that would indicate voltage when utilized if voltage was present on the line and/or load side of the disconnecting device, respectively. These test points are not necessary for my invention to perform as functionally intended but could act as a method of improving my invention for the purpose of a higher level of convenience.

Referring again to FIG. 1B, (n) is referring to miscellaneous indicating and operating devices that would potentially be mounted on the load compartment door. These are shown only to illustrate my example. The quantity, type, position, and otherwise of these devices is non-essential to a preferred embodiment of my invention.

Referring again to FIG. 1B, (o) is referring to the hinging location for a preferred embodiment of my invention. The location shown is typical for low-voltage motor control centers. The hinges would not necessarily need to be located here or used at all if a different mode of achieving the same functionality were to be used.

Referring again to FIG. 1B, (p) is referring to access restricting screw(s), bolt(s), or other device which requires special tool or key (e.g. screwdriver) to defeat.

Referring again to FIG. 1B, (q) is depicting a viewport which would allow a person standing in front of it a thru-door view of the disconnect device that would be mounted within the disconnect compartment without exposing the person, electrically, to the components within the compartment which may or may not be energized. This device is non-essential to a preferred embodiment of my invention but could be used to improve my invention for the purpose of a higher level of convenience.

Referring again to FIG. 1B, (r) is referring to the plate, door, or the like which would act as a barrier for the front of the disconnect compartment to segregate the internals of the compartment from external space.

Referring again to FIG. 1B, (s) is referring to a door securing device (e.g. quarter turn latch) for the load compartment door. This device may or may not be used in a preferred embodiment of my invention.

Referring again to FIG. 1B, (t) is referring to the plate, door, or the like which would act as a barrier for the front of the load compartment to segregate the internals of the compartment from external space.

Referring again to the Drawings, assume it is necessary to perform maintenance to or replace a load device being fed power through the disconnect. The technician switches the disconnect handle to the OFF position. The technician then can open the load compartment door. Following standard safety procedures the technician then verifies that the conductors are de-energized and can now service the device. At this point he can perform his work without concern of violating regulations as the compartment he is working in is completely de-energized of all voltage. This scenario is preferable to de-energizing the service to the disconnect as would be required with a typical system or working within an energized compartment.

Referring to the Drawings, we see diagrammatic views representing a preferred embodiment of my invention. I will here describe, in more detail, the arrangement of the components in reference to the provided drawings;
Referring to the Drawings, the disconnect and load compartments could be either a single (sub)unit which compartmentalizes a plurality of sub-compartments which are here referred to as the disconnect compartment and the load compartment. The sub-compartments could also be stand-alone compartments fashioned together in the arrangement depicted.
Referring again to the Drawings, the disconnect compartment contains a disconnecting device, conductors as necessary, and mechanical linkage or flexible cable as necessary to interlock with the operator handle. Depicted in the drawing are line/load voltage indicators as well as voltage present test points which are optional components to this invention. The viewport shown as item (q) in FIG. 1B is another optional component. The disconnecting device compartment door would preferably be fastened on or closed in such a way that it would require a screwdriver or other special tool to open.
Referring again to the Drawing, the load compartment contains the load device(s) (e.g. Fuse(s), Full Voltage Starter, Reduced Voltage Soft Starter, Variable Frequency Drive, or the like), and an operator handle which is interlocked with the door of the load compartment and switches the remote disconnecting device between its plurality of states (e.g. ON, OFF, etc.). Referring to FIG. 1B item (n), these operators and indicators are shown mounted on the load compartment door and are not necessarily shown in any placement, quantity, mode that would be necessary to achieve the functionality of my invention.
Referring again to the Drawing, incoming power is fed into the disconnect compartment and terminated on the line side of the disconnecting device, power is continued from the load side of the disconnecting device to the load compartment. The power coming into the load compartment is routed to the line side of the load device, power is continued from the load side of the load device to that which it feeds power (i.e. it may be terminated on terminals, lugs, or the like within the load compartment and/or continue to the device(s) or system to which it is feeding power.

To manufacture my invention:
The manufacturing entity would mount and wire or modify/alter the current method of manufacturing motor control center subunit(s) as necessary for each of the following aspects of the electrical motor control center assembly within their respective compartments, while following the necessary guidelines that I have previously laid out within this document.
   Disconnecting device(s)
   Disconnect auxiliary device(s)
   Motor Control Center Unit(s)
   Motor Control Center Subunit(s)
   Conductors
   Doors and cover plates as necessary
   Load Components
   Lugs
   Wireway(s)/Gutter(s)
   Other Devices, as necessary (e.g. auxiliary contacts, voltage testing terminals, conductors, mechanical linkage, and the like)
Components and methods such as; through-wall disconnect operators, interlocking handles, interlocked auxiliary contacts, doors and covers with appropriate gaskets, and the like should be used so that the integrity of isolating the compartments, from each other and a person standing in front of the system, remains in tact.
The compartments should be arranged in such a way to allow for operation and interaction of the complete system in the mode that I have described within this document.
In the preferred embodiment of my invention; all of the individual compartments would be arranged and/or mounted within a motor control center section/unit or arranged in such a way as to carry out the same operation in the way that I have previously described.

I have herein described the preferred embodiment of the present invention in one form that would be useful for electrical motor control center assemblies. The specific arrangement may vary depending on project specific requirements, and desired optional features. It is recognized that equivalents, alternatives, and modifications, aside from those expressly stated, are possible and within the scope of the appending claims.

What I claim as my invention is:

1. A motor control center subunit(s) (bucket(s)) with compartmentalized disconnect, in separate compartment, associated with a distinctly separate load compartment, consisting of multiple compartments arranged so as to allow service of or access to the load compartments without exposure to line voltages.

2. The motor control center subunit(s) (bucket(s)) with compartmentalized disconnect, in separate compartment, associated with a distinctly separate load compartment of claim 1 wherein the disconnecting device(s) (e.g. circuit breakers, or non-trip disconnects) is compartmentalized separately from the load device(s), so as to have no line voltages present in the load compartment when disconnecting device is open.

3. The motor control center subunit(s) (bucket(s)) with compartmentalized disconnect, in separate compartment, associated with a distinctly separate load compartment of claim 1 wherein the disconnect handle interlocks with the load compartment door to prevent access to the load compartment when the corresponding handle is in the ON position, as the load compartment may be energized by the remote disconnect unit in this state.

4. The motor control center subunit(s) (bucket(s)) with compartmentalized disconnect, in separate compartment, associated with a distinctly separate load compartment of claim 1 wherein the disconnect handle interlocks with the load compartment door to grant access to the motor controller compartment when the handle is in the OFF position, as the compartment is de-energized by the disconnecting device in this state.

5. The motor control center subunit(s) (bucket(s)) with compartmentalized disconnect, in separate compartment, associated with a distinctly separate load compartment of claim 1 wherein the modular compartments are contained within an overall enclosure or arranged in a fashion that accomplishes the same functionality.
